(19) United States
(12) Patent Application Publication
(10) Pub. No.: US 2004/0239401 A1
(43) Pub. Date: Dec. 2, 2004

(54) Zero-voltage-switching full-bridge converter

(76) Inventor: Chi-Shun Liao, Taoyuan City (TW)

Correspondence Address: Jackson Walker L.L.P., Suite 2100, 112 E. Pecan Street, San Antonio, TX, 78205, US

(21) Appl. No.: 10/445,781

(22) Filed: May 27, 2003

(51) Int. Cl. H03K 17/56

(52) U.S. Cl. 327/423

(57) ABSTRACT

A zero-voltage-switching full bridge converter has first and second switching units between which a transformer is coupled. Each switching unit is composed of two MOSFETs as the switching elements and controlled by a non-overlap gate driver. For either the first switching unit or the second switching unit, the activated periods of the driving signals for the two switching elements do not overlap. Therefore, the switching loss of the full bridge converter is mitigated.

### BACKGROUND OF THE INVENTION

1. Field of Invention

The present invention relates to a zero-voltage-switching full bridge converter, and more particularly to a zero-voltage-switching (ZVS) converter having the advantage of low switching loss.

2. Related Art

With reference to FIG. 4, a conventional full-bridge converter is composed of two pairs of MOSFETs (QA, QD)(QB, QC) as switching elements. A transformer (51) with a primary side connects between the two switching elements (QA, QC). The first pair of switching elements (QA, QD) is connected to a first logic element (52), and similarly the second pair of switching elements (QB, QC) is connected to a second logic element (53).

With reference to FIG. 5, two driving signals respectively for the two pairs of switching elements (QA, QD)(QB, QC) are illustrated. By properly controlling the two logic elements (52)(53) to output the driving signals, the switching elements (QA, QD)(QB, QC) are alternately activated/deactivated, whereby the energy is able to be transformed from the primary side to the secondary side.

With reference to FIG. 4 again, when the first pair of switching elements (QA, QD) are simultaneously activated, a current path is formed as shown with the broken lines, so the secondary side of the transformer (51) has an induced voltage. Further, when the second pair of switching elements (QB, QC) are activated, a different current path is formed as shown in FIG. 6. The secondary side of the transformer (51) also generates an induced voltage but with the opposite polarity to the induced voltage caused from the activation of the switching elements (QA, QD).

With reference to FIG. 5, deat-time a period denoted with AA, during which all MOSFETs are deactivated, exists between the activated time of the two pairs of switching elements (QA,QD)(QB,QC). In the AA period, the operating voltage Vpp is deemed as being equally distributed over two switching elements. For example, the voltage value of each of the two switching elements (QA and QB) is approximately a half of the operating voltage Vpp. Once the driving signal level for the switching element (QB) is changed from low to high, the sudden activation of the switching element (QB) will cause the problem of switching loss because of the existing voltage. Accordingly, considerable heat will be generated and dissipation of that heat creates a further problem. Thus, a large heat sink is applied to cool the switching elements (QA-QD).

A zero-voltage-switching full bridge converter in accordance with the present invention obviates or mitigates the aforementioned drawbacks.

### SUMMARY OF THE INVENTION

The main objective of the present invention is to provide a zero-voltage-switching (ZVS) full bridge converter composed of plural switching elements, wherein each switching element is activated in a condition of zero-voltage to mitigate the switching loss.

To achieve the objective of the present invention, the ZVS full bridge converter activated by a driving circuit that has two logic elements, comprises:

a first switching unit composed of two switching elements (QA, QB) both connected to a first non-overlap driver;

a second switching unit composed of two switching elements (QC, QD) both connected to a second non-overlap driver;

a transformer coupled between the first switching unit and the second switching unit;

wherein the first non-overlap driver and the second non-overlap [Is driver are respectively connected to the two logic elements of the driving circuit, wherein the activated periods of the two switching elements (QA, QB) of first switching unit are not overlapped, and the activated periods of the two switching elements (QC, QD) are not overlapped either.

Other objectives, advantages and novel features of the invention will become more apparent from the following detailed description when taken in conjunction with the accompanying drawings.

### BRIEF DESCRIPTION OF THE DRAWINGS

FIG. 1 is a circuit diagram of a zero-voltage-switching (ZVS) full bridge converter in accordance with the present invention;

FIG. 2 shows driving signals waveforms and voltage waveforms of the ZVS full bridge converter of FIG. 1;

FIGS. 3A-3E show the circuit operation in sequence of the ZVS full bridge converter in accordance with the present invention;

FIG. 4 is a circuit diagram of a conventional full bridge converter showing two switching elements (QA,QD) are activated;

FIG. 5 is a time sequential view of driving signals for the full bridge converter of FIG. 4; and

FIG. 6 is a circuit diagram of the conventional full bridge converter showing two switching elements (QB,QC) are activated.

### DETAILED DESCRIPTION OF THE INVENTION

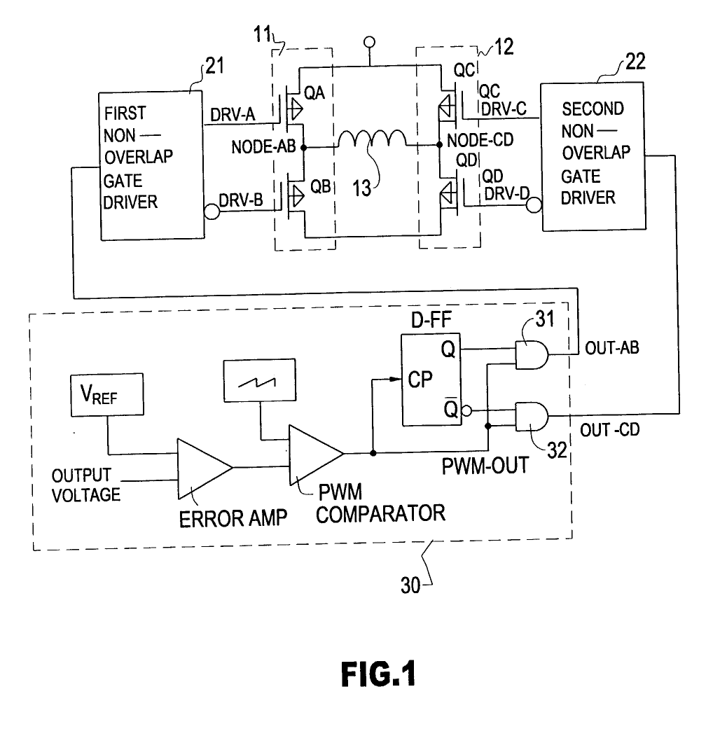

With reference to FIG. 1, a zero-voltage-switching full bridge converter comprises a full bridge converter (not numbered), a first non-overlap gate driver (21), a second non-overlap gate driver (22) and a driving circuit (30).

The ZVS full bridge converter is composed of two switching units (11)(12) and a transformer (13) coupled between the two switching units (11)(12). The first switching unit (11) is consisted of two MOSFETs as the switching elements (QA, QB) connected together at a node designated with NODE-AB. Similarly, the second switching unit (12) is composed of two MOSFETs as the switching elements (QC, QD) connected together at a node designated with NODE-CD.

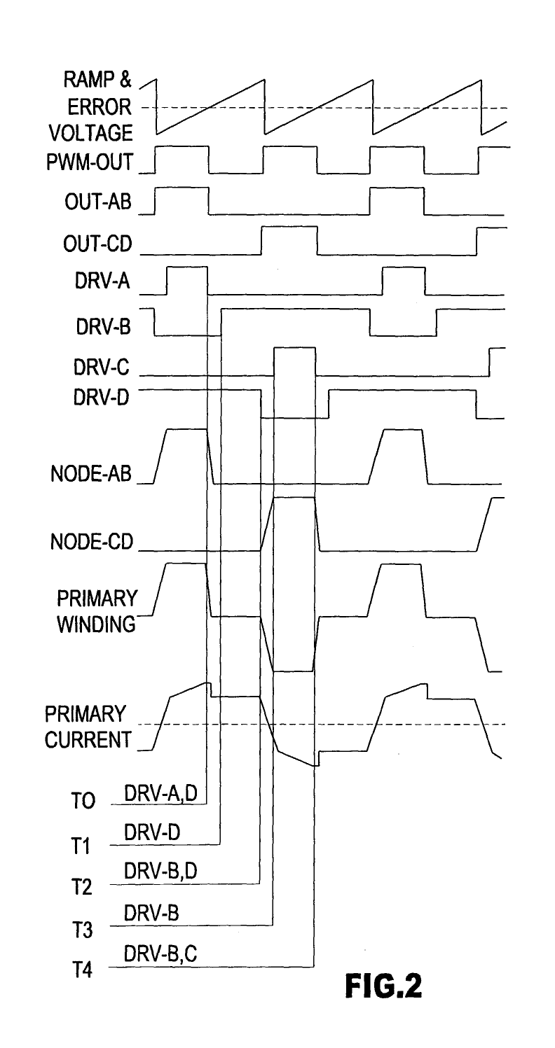

The first non-overlap gate driver (21) has two output terminals respectively connected to the gates of the two switching elements (QA, QB). The driving signals from the first non-overlap gate driver (21) are illustrated in FIG. 2 and denoted with DRV-A and DRV-B. Further, the second non-overlap gate driver (21) also has two output terminals respectively connected to the gates of the two switching elements (QC, QD). The driving signals from the second non-overlap gate driver (22) are illustrated in FIG. 2 and denoted with DRV-C and DRV-D. It is noted that the activated time of the two driving signals DRV-A and DRV-B are not overlapped, and neither are the two driving signals DRV-C and DRV-D.

The driving circuit (30) has two logic elements (31)(32) respectively connected and outputting control signals (OUT-AB and OUT-CD as shown in FIG. 2) to the first and second non-overlap gate drivers (21)(22).

To more clearly show the operation of the present invention, the circuit is sequentially explained hereinafter by five stages divided by the time points T0-T4.

1. The first stage, before T0

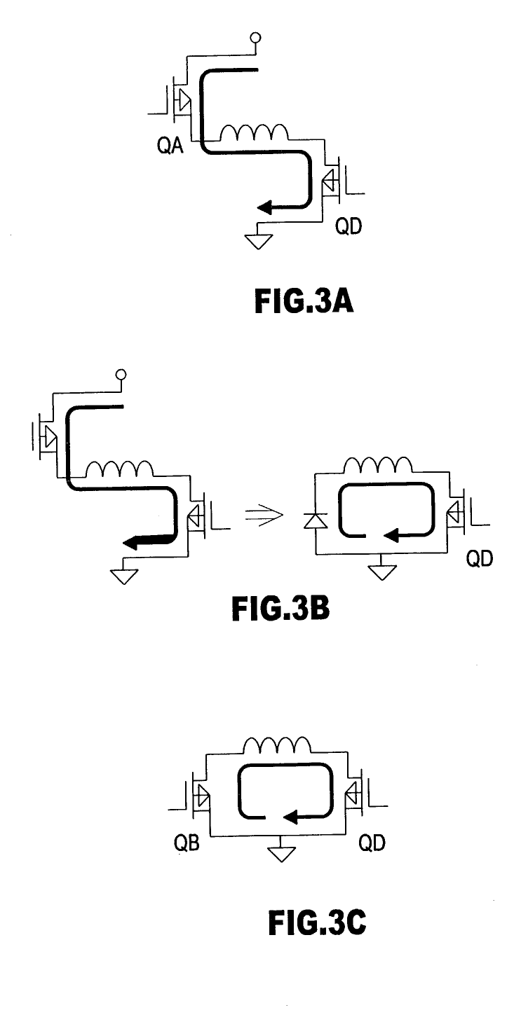

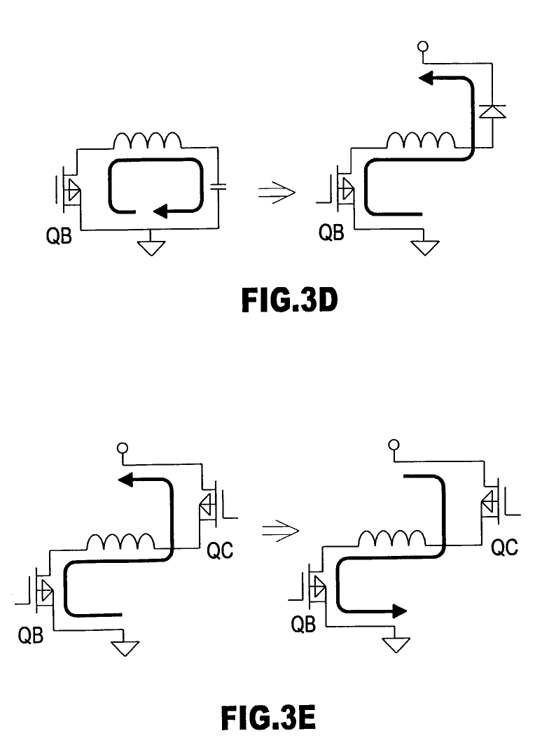

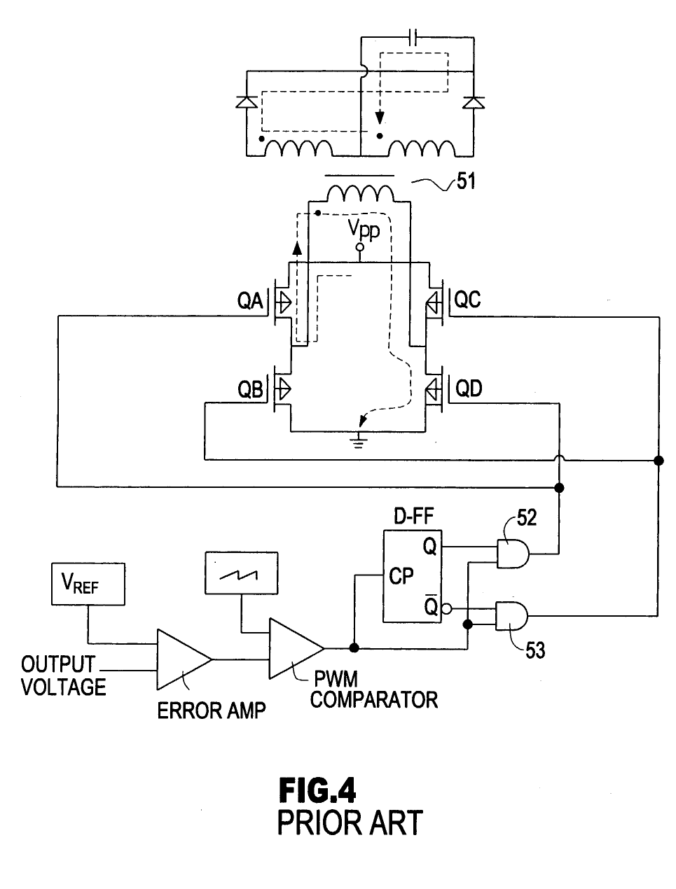

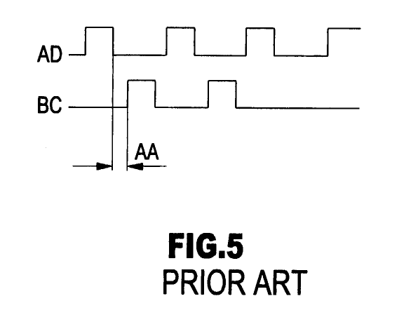

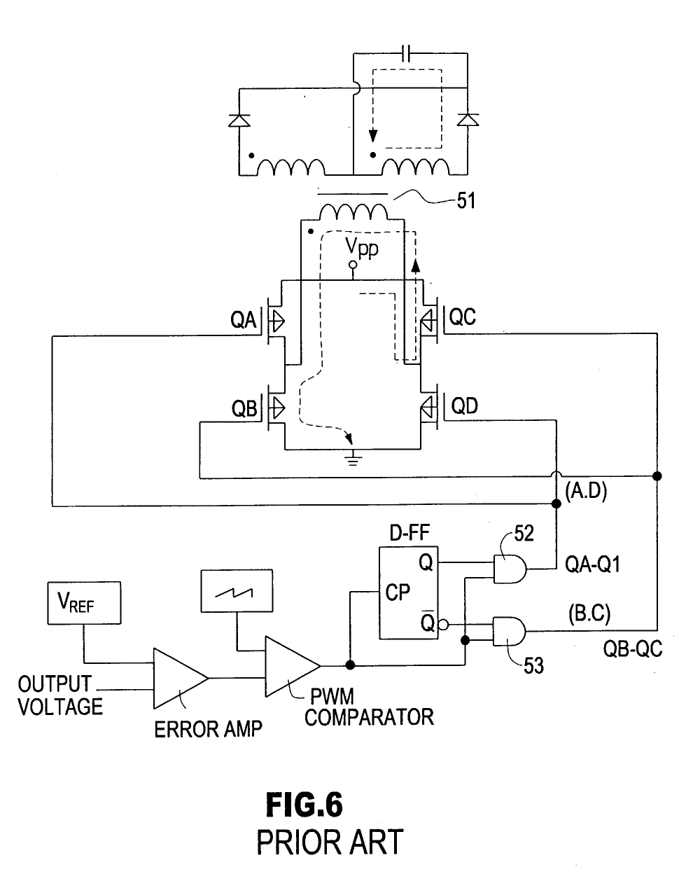

With reference to FIGS. 2 and 3A, the two switching elements (QA and QD) are both activated before the time T0. Thus, a current is able to flow through the primary side of the transformer (13), and the secondary side (not shown) of the transformer (13) will accordingly generate an induced voltage. Because the transformer (13) is constructed with coils, the transformer (13) has the leakage inductance. Leakage inductance occurs when the current flows, and the leakage inductance will store energy that is direct proportion to the square value of the current intensity.

2. The second stage, between T0-T1

With reference to FIGS. 2 and 3B, the switching element (QA) will be deactivated and then deemed as a capacitor, wherein the energy stored in the leakage inductance will charge the capacitor. Thus, the voltage level at the node (NODE-AB) drops from the high voltage level to zero (GND). When the voltage level at the node (NODE-AB) becomes zero, the body diode of the switching element (QB) provides a path for the leakage inductance current.

3. The third stage, between T1-T2

With reference to FIGS. 2 and 3C, the switching elements (QB and QD) both are activated, the inductance current is expressed as di/dt=V/L. The voltage of the primary side is zero, and there is almost no current variation, i.e. the current value is steady and kept as a constant. The energy stored in the leakage inductance is not consumed. Because the voltage level of the node (NODE-AB) becomes zero before the time T1, the objective of zero voltage switching is accomplished at the moment that the switching element (QB) is activated.

4. The fourth stage, between T2-T3

With reference to FIGS. 2 and 3D, the switching element (QD) will be deactivated and then deemed as a capacitor, wherein the energy stored in the leakage inductance will charge the capacitor. Thus, the voltage level at the node (NODE-CD) rises from the zero (GND) to the high voltage level. When the voltage level at the node (NODE-CD) becomes the high voltage level, the body diode of the switching element (QC) provides a path for the leakage inductance current.

5. The fifth stage, between T3-T4

With reference to FIGS. 2 and 3E, both the switching elements (QB and QC) are activated. The voltage polarity of the primary side of the transformer (13) is opposite to the voltage polarity that occurred before T0. Because the voltage level of the node (NODE-CD) becomes zero before the time T3, the zero-voltage switching is accomplished at the moment that the switching element (QC) is activated at T3. The time point T4 is deemed as a start point (T0) of the next cycle, and then the full bridge converter repeats the above mentioned five stages.

From the foregoing description, there is no switching loss at the four switching elements, i.e. the MOSFETs, because of the zero-voltage switching so that the problem of high operation temperature is mitigated.

The invention may be varied in many ways by a skilled person in the art. Such variations are not to be regarded as a departure from the spirit and scope of the invention, and all such modifications are intended to be included within the scope of the following claims.

What is claimed is:

1. A zero-voltage-switching full bridge converter comprising:
a first switching unit composed of two switching elements (QA, QB) both connected at a first node (AB);
a second switching unit composed of two switching elements (QC, QD) both connected at a second node (CD);
a transformer coupled between the first switching unit and the second switching unit;
a first non-overlap gate driver with two output terminals respectively connected to the two switching elements (QA, QB) of the first switching unit for activating the two switching elements (QA, QB);
a second non-overlap gate driver with two output terminals respectively connected to the two switching elements (QC, QD) of the second switching unit for activating the two switching elements (QC, QD);
wherein activated periods of the two switching elements (QA, QB) do not overlap each other, and activated periods of the two switching elements (QC, QD) do not overlap each other either.

2. The zero-voltage-switching full bridge converter as claimed in claim 1, wherein the transformer is connected between the first node and the second node, and the first switching unit and the second switching unit are sequentially operated with five stages and repeat the five stages that includes:
a first stage, wherein the two switching elements (QA and QB) of the first switching unit, and a current flows through a primary side of the transformer, whereby a secondary side of the transformer has an induced voltage;
a second stage, wherein the switching element (QA) is deactivated, and a voltage level at the first node drops from a high level to zero (GND);
a third stage, wherein the switching element (QB) of the first switching unit and the switching element (QD) of the second switching unit are both activated, and the voltage at the primary side of the transformer is zero;
a fourth stage, wherein the switching element (QD) is deactivated, and a voltage level at the second node rises from zero (GND) to a high voltage level; and
a fifth stage, wherein the switching element (QB) of the first switching unit and the switching element (QC) of the second switching unit are both activated, the voltage at the primary side of the transformer has an opposite polarity to the voltage at the first stage.
